(19) United States
(12) Patent Application Publication
(10) Pub. No.: US 2009/0230555 A1
(43) Pub. Date: Sep. 17, 2009

(54) TUNGSTEN LINER FOR ALUMINUM-BASED ELECTROMIGRATION RESISTANT INTERCONNECT STRUCTURE

(75) Inventors: Jonathan D. Chapple-Sokol, Essex Junction, VT (US); Daniel A. Delibac, Colchester, VT (US); Zhong-Xiang He, Essex Junction, VT (US); Tom C. Lee, Essex Junction, VT (US); William J. Murphy, North Ferrisburgh, VT (US); Timothy D. Sullivan, Underhill, VT (US); David C. Thomas, Richmond, VT (US); Daniel S. Vanslette, Fairfax, VT (US)

Correspondence Address: SCULLY, SCOTT, MURPHY & PRESSER, P.C., 400 GARDEN CITY PLAZA, Suite 300, GARDEN CITY, NY, 11530, US

(73) Assignee: INTERNATIONAL BUSINESS MACHINES CORPORATION, Armonk, NY (US)

(21) Appl. No.: 12/049,698

(22) Filed: Mar. 17, 2008

(51) Int. Cl. H01L 23/532; H01L 21/768

(52) U.S. Cl. 257/751; 438/627; 257/E23.157; 257/E21.582

(57) ABSTRACT

An underlying interconnect level containing underlying W vias embedded in a dielectric material layer are formed on a semiconductor substrate. A metallic layer stack comprising, from bottom to top, a low-oxygen-reactivity metal layer, a bottom transition metal layer, a bottom transition metal nitride layer, an aluminum-copper layer, an optional top transition metal layer, and a top transition metal nitride layer. The metallic layer stack is lithographically patterned to form at least one aluminum-based metal line, which constitutes a metal interconnect structure. The low-oxygen-reactivity metal layer enhances electromigration resistance of the at least one aluminum-based metal line since formation of compound between the bottom transition metal layer and the dielectric material layer is prevented by the low-oxygen-reactivity metal layer, which does not interact with the dielectric material layer.

### FIELD OF THE INVENTION

The present invention relates to semiconductor structures, and particularly to aluminum-based electromigration resistant metal interconnect structures employing a low-oxygen-reactivity metal layer as a barrier layer, and methods of manufacturing the same.

### BACKGROUND OF THE INVENTION

A metal line comprises a lattice of metal ions and non-localized free electrons. The metal ions are formed from metal atoms that donate some of their electrons to a common conduction band of the lattice, and the non-localized free electrons move with relatively small resistance within the lattice under an electric field. Normal metal lines, excluding superconducting materials at or below a superconducting temperature, have finite conductivity, which is caused by interaction of electrons with crystalline imperfections and phonons which are thermally induced lattice vibrations.

When electrical current flows in the metal line, the metal ions are subjected to an electrostatic force due to the charge of the metal ion and the electric field to which the metal ion is exposed to. Further, as electrons scatter off the lattice during conduction of electrical current, the electrons transfer momentum to the metal ions in the lattice of the conductor material. The direction of the electrostatic force is in the direction of the electric field, i.e., in the direction of the current, and the direction of the force due to the momentum transfer of the electrons is in the direction of the flow of the electrons, i.e., in the opposite direction of the current. However, the force due to the momentum transfer of the electrons is in general greater than the electrostatic force. Thus, metal ions are subjected to a net force in the opposite direction of the current, or in the direction of the flow of the electrons.

High defect density, i.e., smaller grain size of the metal, or high temperature typically increases electron scattering, and consequently, the amount of momentum transfer from the electrons to the conductor material. Such momentum transfer, if performed sufficiently cumulatively, may cause the metal ions to dislodge from the lattice and move physically. The mass transport caused by the electrical current, or the movement of the conductive material due to electrical current, is termed electromigration in the art.

In applications where high direct current densities are used, such as in metal interconnects of semiconductor devices, electromigration causes a void in a metal line or in a metal via. Such a void results in a locally increased resistance in the metal interconnect, or even an outright circuit “open.” In this case, the metal line or the metal via no longer provides a conductive path in the metal interconnect. Formation of voids in the metal line or the metal via can thus result in a product failure in semiconductor devices.

FIG. 1 shows a vertical cross-sectional view of a first prior art aluminum-based metal wire structure comprising a stack of metallic layers, which comprises, from bottom to top, a bottom Ti layer 920, a bottom TiAl₃ layer 922, an aluminum-copper layer 940, a top TiAl₃ layer 948, a top Ti layer 950, and a top TiN layer 960. The first prior art aluminum-based metal wire structure is formed by forming a stack comprising, from bottom to top, the bottom Ti layer 920, the aluminum-copper layer 940, the top Ti layer 950, and the top TiN layer 960. The stack of metallic layers is subjected to an anneal to form the bottom TiAl₃ layer 922 between the bottom Ti layer 920 and the aluminum-copper layer 940 and the top TiAl₃ layer 948 between the aluminum-copper layer 940 and the top Ti layer 950 through interaction of Ti and Al during the anneal. Since an anneal process is required to produce the first prior art aluminum-based metal wire structure, the metallurgy employed in the first prior art aluminum-based metal wire structure is typically referred to as “anneal metallurgy.” Although the bottom Ti layer 920, bottom TiAl₃ layer 922, the top TiAl₃ layer 948, the top Ti layer 950, and the top TiN layer 960 have a higher resistivity than the resistivity of the aluminum-copper layer 930, these layers provide redundant conductive paths so that even if a void is formed in the aluminum-copper layer 940, electrical continuity of the first prior art aluminum-based metal wire structure is still maintained by providing a conduction path in the bottom Ti layer 920, bottom TiAl₃ layer 922, the top TiAl₃ layer 948, the top Ti layer 950, or the top TiN layer 960 around the void.

FIG. 2 shows a vertical cross-sectional view of a second prior art aluminum-based metal wire structure comprising a stack of metallic layers, which comprises, from bottom to top, a bottom Ti layer 920, a bottom TiN layer 930, an aluminum-copper layer 940, an optional top Ti layer 950′, and a top TiN layer 960. The optional top Ti layer 950′ is optional, i.e., may, or may not be present in the second prior art aluminum-based metal wire structure. The second prior art aluminum-based metal wire structure is formed by forming a stack comprising, from bottom to top, the bottom Ti layer 920, the bottom TiN layer 930, the aluminum-copper layer 940, the optional top Ti layer 950′, and the top TiN layer 960 without any anneal to avoid formation of a TiAl₃ layer. Since no anneal process is required to produce the second prior art aluminum-based metal wire structure, the metallurgy employed in the second prior art aluminum-based metal wire structure is typically referred to as “no-anneal metallurgy.”

The bottom TiN layer 930 is intended to serve as a barrier to prevent formation of TiAl₃. The effectiveness of the bottom TiN layer 930 as a barrier layer to the Ti—Al reaction depends on the grain structure and texture of the bottom TiN layer 930 as well as the method of deposition. If the texture of the bottom TiN layer 930 is not tightly oriented, grain boundaries in the bottom TiN layer 930 become easy diffusion paths for the underlying Ti to travel to the aluminum-copper layer 940 and to react with, and/or to diffuse into, the aluminum-copper layer 940 and raise the resistance thereof. For a TiN layer 930 that is formed by deposition of Ti in a nitrogen ambient, the TiN layer 930 can be Ti rich so that Ti diffuses out of the bottom TiN layer 930 and reacts with the aluminum-copper layer 940 on its own, even without the presence of the bottom Ti layer 920 underneath.

The bottom Ti layer 920 in the stack serves multiple purposes, one of which is promotion of adhesion to an underlying dielectric layer (not shown), which typically comprises silicon oxide. However, Ti atoms in the bottom Ti layer 920 interacts with the silicon oxide to form TiOₓSi_{y} compounds which decrease the thickness of the conductive part of the bottom Ti layer 920 in time. The formation of the TiOₓSi_{y} compounds affects the amount of Ti atoms to diffuse from the bottom Ti layer 920 through the bottom TiN layer 930 into the aluminum-copper layer 940 to react with Al. The thickness of the bottom Ti layer 920 is reduced with the formation of the TiOₓSi_{y} compounds, and consequently, the current carrying capacity of the bottom Ti layer 920 and the ability to compensate for formation of voids in the aluminum-copper layer 940 are reduced as the thickness of the bottom Ti layer 920 decreases.

The reduction of thickness in the bottom Ti layer 920 may vary locally, which results in local variations in electromigration (EM) resistance. On one hand, if the bottom Ti layer 920 becomes too thin, the sheet resistance of the bottom Ti layer 920 increases too much, which leads to earlier electromigration failure to a predetermined resistance level, as well as earlier failure by open circuit. On the other hand, increase in the thickness of the bottom Ti layer 920 may result in formation of a thick TiAl₃ layer immediately over a W via located underneath the bottom Ti layer 920. This reduces the volume of the material in the aluminum-copper layer 940 that is required to be removed by electromigration to form a void, thus rendering the second prior art aluminum-based metal wire structure more prone to electromigration and shortening the electromigration life.

Somewhat more subtle effects have been observed as well in the second prior art aluminum-based metal wire structure. Whereas the traditional voiding over a W via observed under electromigration typically clears out all of the AlCu alloy over the W via, a thin flat void sometimes appears over the W via and then expand into a full-line void just past the W via in the in the second prior art aluminum-based metal wire structure. This has the effect of producing a noticeable resistance shift due to electromigration in a shorter time than if the entire volume of AlCu alloy is removed, prompting earlier electromigration failures in the second prior art aluminum-based metal wire structure.

A consequence of such various electromigration effects is that a series of small process changes over several years can degrade the electromigration performance of the metallization. While none of the individual process changes in itself may be important, the combined effects can be significant, and can produce suboptimal results when the metallization process generates a bottom Ti layer 920 and/or a bottom TiN layer 930 having a thickness close to minimum thickness for the respective layers. Statistically, when sufficient quantity of hardware is subjected to electromigration stress, frequency of early failure increases and the usable current density of the metallization degrades.

Variations in the thickness of bottom Ti layer 920 and anneal conditions have been attempted to improve the performance in anneal metallurgy structures such as the first prior art aluminum-based metal wire structure, such an approach induces performance tradeoffs (e.g., resistance per unit) that result in poor yields as dimensions of metallization structures shrink. In addition, lithographic requirements of deep-ultraviolet (DUV) technology often necessitate the use of dielectric ARC layers, which impart stresses on the anneal metallurgy structures such that materials extrude when heated and may induce electrical shorts.

For no anneal metallurgy structures such as the second prior art aluminum-based metal wire structure, a potential solution to electromigration issues may be design rule modifications such as employing redundant vias or extensions. However, such design modifications compromise the designs in areal circuit density and cost. Attempts to add additional Ti layers or TiN layers only have proven to compound the problem of the reaction of Al with Ti.

In view of the above, there exists a need to provide an aluminum-based electromigration resistant metal interconnect structure for semiconductor applications and methods of providing the same.

### SUMMARY OF THE INVENTION

The present invention addresses the needs described above by providing an aluminum-based metal interconnect structure having a higher resistance to electromigration compared to prior art structures and methods of manufacturing the same.

According to the present invention, an underlying interconnect level containing underlying W vias embedded in a dielectric material layer are formed on a semiconductor substrate. A metallic layer stack comprising, from bottom to top, a low-oxygen-reactivity metal layer, a bottom transition metal layer, a bottom transition metal nitride layer, an aluminum-copper layer, an optional top transition metal layer, and a top transition metal nitride layer. The metallic layer stack is lithographically patterned to form at least one aluminum-based metal line, which constitutes a metal interconnect structure. The low-oxygen-reactivity metal layer enhances electromigration resistance of the at least one aluminum-based metal line since formation of compound between the bottom transition metal layer and the dielectric material layer is prevented by the low-oxygen-reactivity metal layer, which does not interact with the dielectric material layer.

According to an aspect of the present invention, a metal interconnect structure is provided, which comprises:

an underlying dielectric layer located on a semiconductor substrate;

an underlying W via embedded in the underlying dielectric layer; and

a metal line comprising a stack of metallic layers and vertically abutting the underlying W via, wherein the stack of metallic layers comprises, from bottom to top, a low-oxygen-reactivity metal layer, a bottom transition metal layer vertically abutting the low-oxygen-reactivity metal layer, a bottom transition metal nitride layer vertically abutting the bottom transition metal layer, an aluminum-copper layer vertically abutting the bottom transition metal nitride layer, and a top transition metal nitride layer located on and above the aluminum-copper layer.

The low-oxygen-reactivity metal layer may vertically abut the underlying W via. Alternately, the stack of metallic layers may further comprise a bottommost transition metal nitride layer located underneath and vertically abutting the low-oxygen-reactivity metal layer, wherein the bottommost transition metal nitride layer abuts the underlying W via.

The underlying W via may have a top surface that is coplanar with a top surface of the underlying dielectric layer. The underlying dielectric layer may comprises a dielectric material selected from undoped silicate glass (USG), fluorosilicate glass (FSG), a porous or non-porous organosilicate glass (OSG), a spin-on dielectric material having a dielectric constant less than 3.0, or a SiCOH based low dielectric constant (low-k) chemical vapor deposition (CVD) material having a dielectric constant less than 3.0.

The metal interconnect structure may further comprise an overlying dielectric layer abutting a top surface and sidewalls of the metal line and abutting a top surface of the underlying dielectric layer. The metal interconnect structure may further comprise another W via vertically abutting a top surface of the metal line and embedded in the overlying dielectric layer.

According to another aspect of the present invention, a method of forming a metal interconnect structure is provided, which comprises:

forming an underlying dielectric layer on a semiconductor substrate;

forming an underlying W via within the underlying dielectric layer;

forming a low-oxygen-reactivity metal layer on the underlying dielectric layer and the W via;

forming a bottom transition metal layer directly on the low-oxygen-reactivity metal layer;

forming a bottom transition metal nitride layer directly on the bottom transition metal layer;

forming an aluminum-copper layer directly on the bottom transition metal nitride layer; and

forming a top transition metal nitride layer on the aluminum-copper layer.

The method may further comprise lithographically patterning the top transition metal nitride layer, the aluminum-copper layer, the bottom transition metal nitride layer, the bottom transition metal layer, and the low-oxygen-reactivity metal layer. The top transition metal nitride layer, the aluminum-copper layer, the bottom transition metal nitride layer, the bottom transition metal layer, and the low-oxygen-reactivity metal layer may be patterned employing a same photoresist by at least one anisotropic etch. Remaining portions of the top transition metal nitride layer, the aluminum-copper layer, the bottom transition metal nitride layer, the bottom transition metal layer, and the low-oxygen-reactivity metal layer collectively constitute a metal line formed on and above the underlying dielectric layer and the underlying W via after the lithographical patterning.

The method may further comprise forming an overlying dielectric layer directly on a top surface and sidewalls of the metal line and directly on a top surface of the underlying dielectric layer. The method may further comprise forming another W via directly on a top surface of the metal line, wherein the other W via is embedded in the overlying dielectric layer.

### BRIEF DESCRIPTION OF THE DRAWINGS

FIG. 1 shows a vertical cross-sectional view of a first prior art aluminum-based metal wire structure comprising a stack of metallic layers.

FIG. 2 shows a vertical cross-sectional view of a second prior art aluminum-based metal wire structure comprising another stack of metallic layers.

FIGS. 3, 4, and 9-13 are sequential vertical cross-sectional views of an exemplary metal interconnect structure at various processing steps of a manufacturing sequence according to the present invention.

FIGS. 5-8 are vertical cross-sectional views of first, second, third, and fourth exemplary structures comprising a stack of metallic layers according to first, second, third, and fourth embodiments of the present invention, respectively.

FIG. 14 is a Log-Normal plot of cumulative failure rate as a function of a logarithm of stress time, which compares performance of the exemplary metal interconnect structure according to the present invention against performance of a prior art metal interconnect structure incorporating the second prior art aluminum-based metal wire structure.

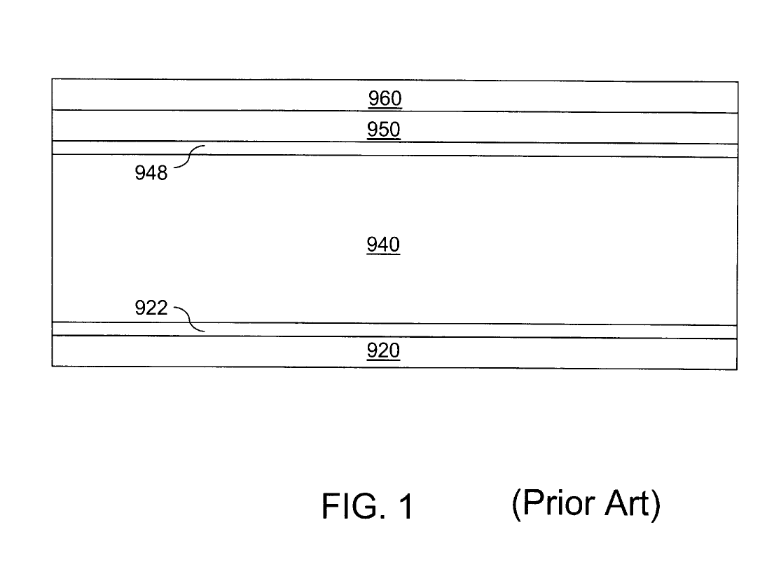

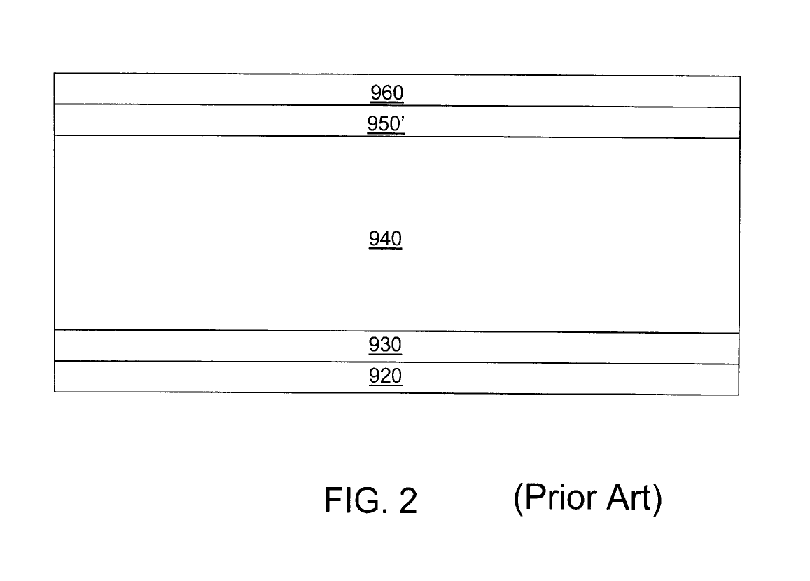

### DETAILED DESCRIPTION OF THE INVENTION

As stated above, the present invention relates to aluminum-based electromigration resistant metal interconnect structures employing a low-oxygen-reactivity metal layer as a barrier layer, and methods of manufacturing the same, which is now described in detail with accompanying figures. It is noted that like and corresponding elements are referred to by like reference numerals.

Referring to FIG. 3, an exemplary metal interconnect structure according to the present invention comprises a semiconductor substrate 100 and an underlying interconnect level 200. The semiconductor substrate 100 comprises a semiconductor layer 110. The semiconductor layer 110 may comprise a single crystalline, i.e., epitaxial, semiconductor material. Alternately, the semiconductor layer 110 may comprise polycrystalline semiconductor material. A shallow trench isolation structure 115, which comprises a dielectric material such as silicon oxide and provide electrical isolation between adjacent semiconductor devices, may be formed in the semiconductor substrate 100. The semiconductor substrate 100 may be a bulk substrate, a semiconductor-on-insulator (SOI) substrate, or a hybrid substrate.

The underlying interconnect level 200 comprises an underlying dielectric layer 270 and an underlying W via 280. The term, “underlying” dielectric layer 270 is employed herein to denote that the underlying dielectric layer 270 is located underneath a metal line comprising a stack of metallic layers of the present invention to be described below. Thus, the term “underlying” dielectric layer 270 denotes the location of the underlying dielectric layer 270 relative to the metal line of the present invention. Likewise, the term, “underlying” interconnect level 200 also denotes that the underlying interconnect level 200 is located beneath the metal line of the present invention.

The underlying interconnect level 200 may optionally comprise elements of semiconductor devices. For example, the underlying interconnect level 200 may comprise a gate dielectric 120, a gate conductor line 130, and a gate spacer 140, which comprise components of a field effect transistor along with a source (not shown) and a drain (not shown), which are doped portions of the semiconductor layer 110.

The underlying dielectric layer 270 may comprise an oxide based dielectric material, which has a dielectric constant k from about 3.6 to about 3.9, or a low-k dielectric material, which has a dielectric constant k of about 3.0 or less, preferably less than about 2.8, and more preferably less than about 2.5. Non-limiting examples of the oxide based dielectric material included undoped silicate glass (USG), fluorosilicate glass (FSG), borophosphosilicate glass (BPSG), and phosphosilicate glass (PSG). Oxide based dielectric materials may be formed by chemical vapor deposition such as plasma enhanced chemical vapor deposition (PECVD), high density plasma chemical vapor deposition (HDPCVD), etc. An exemplary precursor that may be employed to form the oxide based dielectric material is tetra-ethyl-ortho-silicate (TEOS). Other precursors may also be employed to form a film of the oxide based dielectric material.

The underlying dielectric layer 270 may comprise a spin-on low-k dielectric material, i.e., a spin-on dielectric material having a dielectric constant less than 3.0. An example of the spin-on low-k dielectric material is a thermosetting polyarylene ether, which is also commonly referred to as “Silicon Low-K”, or “SiLK™.” The term “polyarylene” is used herein to denote aryl moieties or inertly substituted aryl moieties which are linked together by bonds, fused rings, or inert linking groups such as oxygen, sulfur, sulfone, sulfoxide, carbonyl, etc.

The underlying dielectric layer 270 may comprise a CVD low-k dielectric material, i.e., a low-k dielectric material deposited by chemical vapor deposition (CVD), which include porous or non-porous organosilicate glass (OSG) and SiCOH based low dielectric constant (low-k) chemical vapor deposition (CVD) materials having a dielectric constant less than 3.0. Composition and deposition methods of the CVD low-k dielectric material are well known in the art. SiCOH based low-k CVD materials contain a matrix of a hydrogenated oxidized silicon carbon material (SiCOH) comprising atoms of Si, C, O and H in a covalently bonded tri-dimensional network.

Both the spin-on low-k dielectric material and the CVD low-k dielectric material may be porous, which decreases the dielectric constant of the underlying dielectric layer 270. The underlying dielectric layer 270 may comprise a stack of at least two of the oxide based conventional dielectric material, the spin-on low-k dielectric material, and the CVD low-k dielectric material.

The thickness of the underlying dielectric layer 270 may be 50 nm to about 1 μm, with a thickness from 100 to about 500 nm being more typical, although lesser and greater thicknesses are explicitly contemplated herein. The underlying dielectric layer 270 may be formed directly on the semiconductor substrate 100, or alternately, at least one metal interconnect level (not shown) comprising a dielectric layer and at least one of metal line level structures and metal via level structures may be interposed between the semiconductor substrate 100 and the underlying dielectric layer 270. While the present invention is described employing the exemplary metal interconnect structure, one skilled in the art would recognize that as many metal interconnect levels as needed may be interposed between the semiconductor substrate 100 and the underlying dielectric layer 270 as necessary to enable multi-level metal interconnect structure.

An underlying W via 280 is formed in the underlying dielectric layer 270 by forming a via hole in the underlying dielectric layer 270 by lithographic methods, filling the via hole with W, and removing W above a top surface of the underlying dielectric layer 270. Specifically, the via hole may be formed by application and patterning of a photoresist (not shown). The pattern in the photoresist contains a hole, and the pattern of the hole in the photoresist is transferred into the underlying dielectric layer 270 by an anisotropic etch, such as a reactive ion etch which employs the photoresist as a masking layer. The deposition of low-oxygen-reactivity metal may be performed by chemical vapor deposition (CVD), physical vapor deposition (PVD), or a combination thereof. A suitable metallic liner may be deposited prior to deposition of low-oxygen-reactivity metal to enhance the adhesion of low-oxygen-reactivity metal to the underlying dielectric layer 270 and any other structure located underneath the via hole. The low-oxygen-reactivity metal deposited over the top surface of the underlying dielectric layer 270 may be removed by a recess etch, chemical mechanical planarization (CMP), or a combination thereof. Removal of the portion of the low-oxygen-reactivity metal material above the top surface of the underlying dielectric layer 270 leaves the underlying W via 280 in the via hole. In other words, the remaining portion of the low-oxygen-reactivity metal material in the via hole constitutes the underlying W via 280. The top surface of the underlying W via 280 is coplanar with the top surface of the underlying dielectric layer 270.

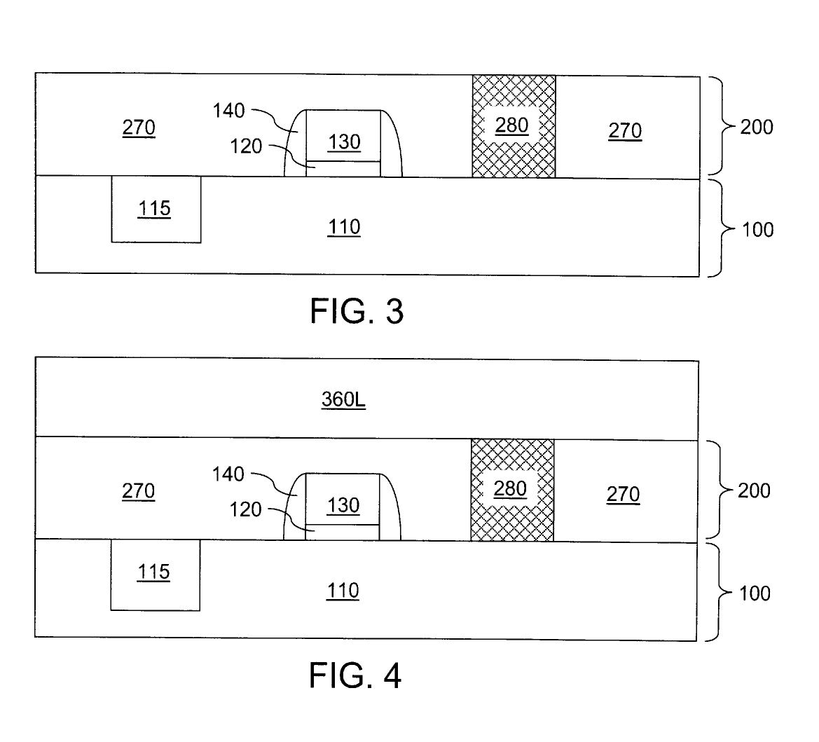

Referring to FIG. 4, a metallic stack 360L is formed directly on the top surface of the underlying dielectric layer 270 and the top surface of the underlying W via 280. The metallic stack 360L comprises a plurality of unpatterned metallic layers, which are deposited by blanket deposition. Each of the metallic layers in the metallic stack 360L is unpatterned since no lithographic patterning is employed between any of consecutive metallic layers in metallic stack 360L. Each of the metallic layer in the metallic stack 360L is a blanket film without any pattern at this point. Thus, the metallic stack 360L is a blanket stack without any pattern therein.

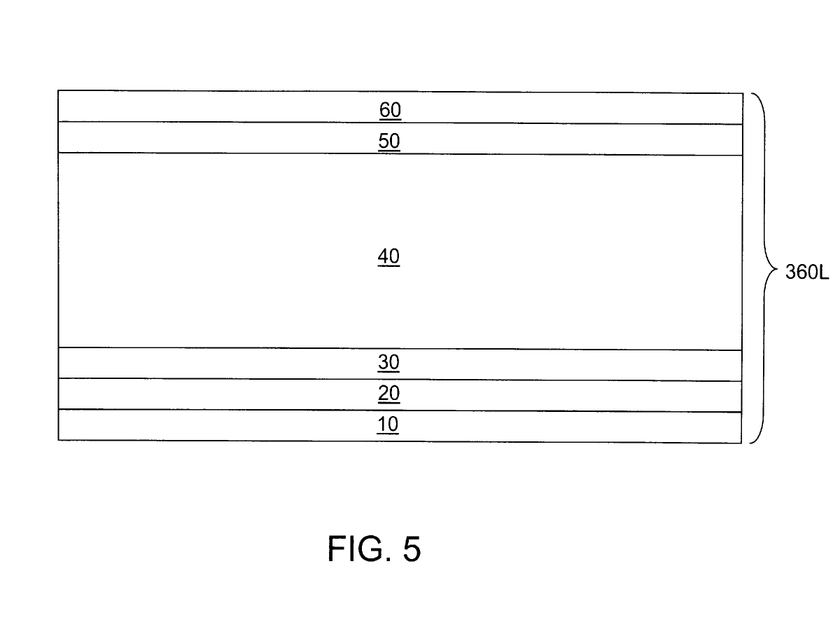

Four embodiments are provided for the structure of the metallic stack 360L according to the present invention. Referring to FIG. 5, a first exemplary structure for the metallic stack 360L is shown according to a first embodiment of the present invention. The first exemplary structure for the metallic stack 360L comprises, from bottom to top, a low-oxygen-reactivity metal layer 10, a bottom transition metal layer 20, a transition metal nitride layer 30, an aluminum-copper layer 40, a top transition metal layer 50, and a top transition metal nitride layer 60. The bottom transition metal layer 20 is formed directly on the low-oxygen-reactivity metal layer 10, and vertically abuts the low-oxygen-reactivity metal layer 10. The bottom transition metal nitride layer 30 is formed directly on the bottom transition metal layer 20, and vertically abuts the bottom transition metal layer 20. The aluminum-copper layer 40 is formed directly on the bottom transition metal nitride layer 30, and vertically abuts the bottom transition metal nitride layer 40. The top transition metal layer 50 is formed directly on the aluminum-copper layer 40, and vertically abuts the aluminum-copper layer 40. The top transition metal nitride layer 60 is formed on the aluminum-copper layer 40, and is located on and above the aluminum-copper layer 40. Specifically, top transition metal nitride layer 60 is formed directly on the top transition metal layer 50, and is located directly on the top transition metal layer 50.

The metallic stack 360L comprising the first exemplary structure of FIG. 5 may be formed on the exemplary metal interconnect structure of FIG. 3 by a series of processing steps that are performed in a clustered toolset. Alternately, the metallic stack 360L comprising the first exemplary structure of FIG. 5 may be formed with air breaks, i.e., exposure to air ambient, between consecutive processing steps. In this case, suitable preclean steps such as degassing at an elevated temperature and/or inert gas sputtering are employed to provide a clean interface between a previously deposited layer and the new layer to be deposited. In case a clustered toolset is employed to form the first exemplary structure for the metallic stack 360L, the clustered toolset may, or may not, include all process chambers needed to form the entirety of the metallic stack 360L comprising the first exemplary structure of FIG. 5. Thus, one or more clustered toolsets may be employed to form the first exemplary structure for the metallic stack 360L.

To incorporate the first exemplary structure of FIG. 5 as the metallic stack 360L into the exemplary metal interconnect structure as shown in FIG. 4, the exemplary metal interconnect structure of FIG. 3 is introduced into a degassing chamber at high vacuum through a transfer system provided with vacuum loadlocks. A degassing step is performed at an elevated temperature in high vacuum to desorb impurity molecules from the underlying surfaces, which include the top surface of the underlying dielectric layer 270 and the top surface of the underlying W via 280. For example, the degassing step may be performed at about 250° C. for about 120 seconds in high vacuum with a base pressure of about 1.0×10⁻⁷ Torr. Preferably, the degassing step is performed at a dedicated degassing chamber attached to a clustered toolset.

The exemplary metal interconnect structure of FIG. 3 is then transferred into a sputter preclean chamber, which is preferably one of chambers of the clustered toolset so that the exemplary metal interconnect structure may be transferred without breaking vacuum. The exemplary metal interconnect structure is then subjected to an inert sputtering gas such as Ar. The sputter cleaning process employs the inert sputtering gas to clean the exposed surfaces of the exemplary metal interconnect structure. The exposed surface portions of the underlying dielectric layer 270 and the underlying W via 280 are removed by sputtering from the exposed surfaces of the exemplary metal interconnect structure. Typically, non-directional inductive plasma is employed in the sputtering process. The amount of removed material from the underlying dielectric layer 270 and the underlying W via 280 corresponds to a reduction of thickness by about 5 nm, although lesser or more materials may be removed by the sputter cleaning process.

The exemplary metal interconnect structure of FIG. 3 is then transferred into a low-oxygen-reactivity metal deposition chamber, which is preferably one of chambers of the clustered toolset so that the exemplary metal interconnect structure may be transferred without breaking vacuum. The low-oxygen-reactivity metal layer 10 may be formed by physical vapor deposition (PVD) or chemical vapor deposition (CVD). Depending on the deposition method employed, the low-oxygen-reactivity metal deposition chamber may be a PVD chamber or a CVD chamber. Preferably, the low-oxygen-reactivity metal layer 10 is formed by physical vapor deposition in a PVD chamber in high vacuum. low-oxygen-reactivity metal material deposited by PVD provides higher adhesion strength than low-oxygen-reactivity metal material deposited by CVD. The low-oxygen-reactivity metal layer 10 comprises low-oxygen-reactivity metal as elemental metal. Preferably, the low-oxygen-reactivity metal layer 10 consists of low-oxygen-reactivity metal as elemental metal, i.e., the concentration of impurities in the low-oxygen-reactivity metal layer 10 is at a trace level, if any. The low-oxygen-reactivity metal layer 10 has a thickness from about 5 nm to about 100 nm, although lesser and greater thicknesses are also contemplated herein also.

The low-oxygen-reactivity metal layer 10 comprises an elemental having low reactivity with oxygen. The low-oxygen-reactivity metal layer 10 may be selected from W, Mo, Ta, Pt, Co, Pd, and Ni. Preferably, the low-oxygen-reactivity metal layer 10 comprises an elemental metal having a high melting temperature and low resistivity so that the current conduction is not limited by the material properties of the low-oxygen-reactivity metal layer 10 and local heating is prevented. In this regard, the low-oxygen-reactivity metal layer 10 is preferably selected from W, Mo, Ta, Pt, Co, and Pd, which have a melting temperature greater than 2,600° C. More preferably, the low-oxygen-reactivity metal layer 10 may be selected from W, Mo, Ta, and Pt, which have low resistivity, high melting temperature, and low reactivity. Most preferably, the low-oxygen-reactivity metal layer 10 comprises W. Preferably, the low-oxygen-reactivity metal layer 10 consists of a single elemental metal selected from W, Mo, Ta, Pt, Co, Pd, and Ni.

Subsequently, the exemplary metal interconnect structure is transported to a transition metal deposition chamber for deposition of the bottom transition metal layer 20. The transport may be effected in vacuum without exposing the exemplary metal interconnect structure to air ambient, or may be subjected to an air break during transfer to the transition metal deposition chamber. In case the exemplary metal interconnect structure is subjected to an air break, a second degassing step is preferred prior to deposition of the bottom transition metal layer 20 in the transition metal deposition chamber. Typically, the second degassing step employs a degassing chamber in which the temperature of the exemplary metal interconnect structure is maintained at a temperature from about 150° C. to about 250° C. The exemplary metal interconnect structure is subjected to the degassing process for about 120 seconds in high vacuum with a base pressure of about 1.0×10⁻⁷ Torr.

The bottom transition metal layer 20 is formed by physical vapor deposition (PVD) of an elemental metal in high vacuum in the transition metal deposition chamber. The elemental metal is a transition metal selected from the elements in group III B, group IV B, group V B, group VI B, group VII B, group VIII B, group I B, and group II B. The transition metal may be one of inner transition elements, i.e., Lanthanides and Actinides. Particularly, the bottom transition metal layer 20 may comprise Ti or Ta. Preferably, the bottom transition metal layer 20 comprises Ti as elemental metal. More preferably, the bottom transition metal layer 20 consists of Ti as elemental metal, i.e., the concentration of impurities in the bottom transition metal layer 20 is at a trace level, if any. The bottom transition metal layer 20 has a thickness from about 5 nm to about 50 nm, although lesser and greater thicknesses are also contemplated herein also.

The exemplary metal interconnect structure is then transported to a transition metal nitride deposition chamber, which is preferably one of chambers of the same clustered toolset to which the transition metal deposition chamber belongs. In this case, the exemplary metal interconnect structure may be transferred without breaking vacuum into the transition metal nitride deposition chamber. The bottom transition metal nitride layer 30 is formed by physical vapor deposition (PVD) of a transition metal nitride in high vacuum in the transition metal nitride deposition chamber.

The transition metal nitride is a conductive nitride of a transition metal, in which the transition metal is selected from the elements in group III B, group IV B, group V B, group VI B, group VII B, group VIII B, group I B, and group II B of the Periodic Table of Elements. The transition metal may be one of inner transition elements, i.e., Lanthanides and Actinides. Preferably, the bottom transition metal nitride layer 30 comprises a conductive nitride of the elemental transition metal of the bottom transition metal layer 20. In a preferred case, the bottom transition metal layer 20 comprises Ti and the bottom transition metal nitride layer 30 comprises TiN. In another case, the bottom transition metal layer 20 comprises Ta and the bottom transition metal nitride layer 30 comprises TaN. Preferably, the bottom transition metal nitride layer 30 consists of the transition metal nitride, i.e., the concentration of impurities in the bottom transition metal nitride layer 30 is at a trace level, if any. The bottom transition metal nitride layer 30 has a thickness from about 5 nm to about 100 nm, although lesser and greater thicknesses are also contemplated herein also.

The exemplary metal interconnect structure is thereafter transported to an Al—Cu deposition chamber, which is preferably one of chambers of the same clustered toolset to which the transition metal nitride deposition chamber belongs. In this case, the exemplary metal interconnect structure may be transferred without breaking vacuum into the transition metal nitride deposition chamber. The aluminum-copper layer 40 is formed by physical vapor deposition (PVD) of an aluminum-copper alloy in high vacuum in the Al—Cu deposition chamber. The temperature of the PVD process for deposition of the aluminum-copper layer 40 may be from about 200° C. to about 250° C., although lower and higher temperatures are also contemplated herein.

The aluminum-copper layer 40 comprises an aluminum-copper alloy containing about 0.5 weight percentage copper, the balance of the aluminum-copper alloy comprising aluminum. In other words, aluminum-copper alloy consists of about 99.5 weight percentage aluminum and about 0.5 weight percentage copper. The aluminum-copper layer 40 has a thickness from about 100 nm to about 4,000 nm, although lesser and greater thicknesses are also contemplated herein also. Al-0.5 wt % Cu is just one alloy of many. Other alloys in varying weight % include Cu, Si, Ti, or Ta, singly, or in combination.

Next, the exemplary metal interconnect structure is transported to the transition metal deposition chamber for deposition of the top transition metal layer 50. Preferably, the exemplary metal interconnect structure is transferred in vacuum without being exposed to air ambient.

The top transition metal layer 50 is formed by physical vapor deposition (PVD) of an elemental metal in high vacuum in the transition metal deposition chamber. The elemental metal is a transition metal selected from the elements in group III B, group IV B, group V B, group VI B, group VII B, group VIII B, group I B, and group II B of the Periodic Table of Elements. The transition metal may be one of inner transition elements, i.e., Lanthanides and Actinides. Particularly, the top transition metal layer 50 may comprise Ti or Ta. Preferably, the top transition metal layer 50 comprises Ti as elemental metal. More preferably, the top transition metal layer 50 consists of Ti as elemental metal, i.e., the concentration of impurities in the top transition metal layer 50 is at a trace level, if any. The top transition metal layer 50 has a thickness from about 2 nm to about 20 nm, although lesser and greater thicknesses are also contemplated herein also.

The exemplary metal interconnect structure is thereafter transported to the transition metal nitride deposition chamber for deposition of the top transition metal nitride layer 60. Preferably, the exemplary metal interconnect structure is transferred in vacuum without being exposed to air ambient.

The top transition metal nitride layer 60 is formed by physical vapor deposition (PVD) of a transition metal nitride in high vacuum in the transition metal nitride deposition chamber. The transition metal nitride is a conductive nitride of a transition metal, in which the transition metal is selected from the elements in group III B, group IV B, group V B, group VI B, group VII B, group VIII B, group I B, and group II B of the Periodic Table of Elements. The transition metal may be one of inner transition elements, i.e., Lanthanides and Actinides. Preferably, the top transition metal nitride layer 60 comprises a conductive nitride of the elemental transition metal of the top transition metal layer 50. In a preferred case, the top transition metal layer 50 comprises Ti and the top transition metal nitride layer 60 comprises TiN. In another case, the top transition metal layer 50 comprises Ta and the top transition metal nitride layer 60 comprises TaN. Preferably, the top transition metal nitride layer 60 consists of the transition metal nitride, i.e., the concentration of impurities in the top transition metal nitride layer 60 is at a trace level, if any. The top transition metal nitride layer 60 has a thickness from about 35 nm to about 200 nm, although lesser and greater thicknesses are also contemplated herein also.

As discussed above, the low-oxygen-reactivity metal layer 10, the bottom transition metal layer 20, the transition metal nitride layer 30, the aluminum-copper layer 40, the top transition metal layer 50, and the top transition metal nitride layer 60 collectively constitute the first exemplary structure of FIG. 5, which is the metallic stack 360L in the exemplary metal interconnect structure of FIG. 4 according to the first embodiment of the present invention.

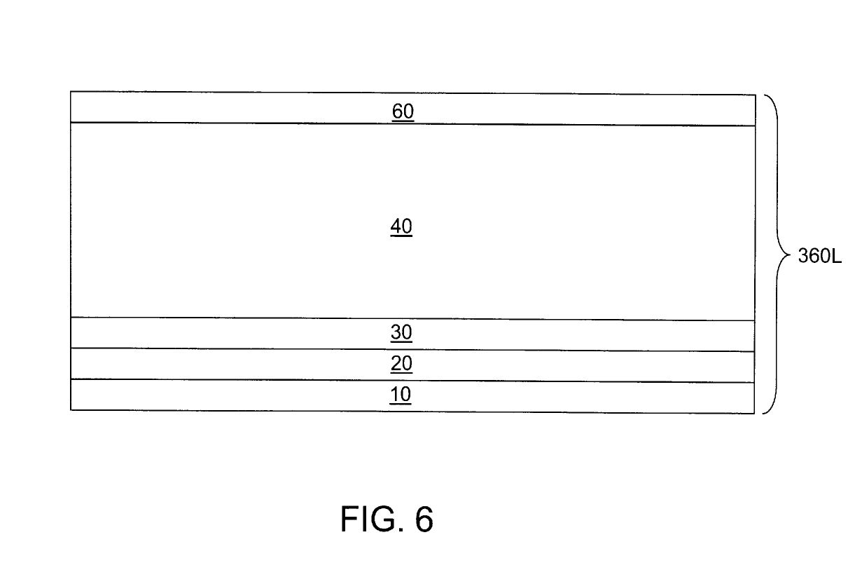

Referring to FIG. 6, a second exemplary structure for the metallic stack 360L is shown according to a second embodiment of the present invention. The second exemplary structure for the metallic stack 360L may be incorporated into the exemplary metal interconnect structure of FIG. 4 instead of the first exemplary structure for the metallic stack 360L. The second exemplary structure for the metallic stack 360L comprises, from bottom to top, a low-oxygen-reactivity metal layer 10, a bottom transition metal layer 20, a transition metal nitride layer 30, an aluminum-copper layer 40, and a top transition metal nitride layer 60.

The structure, composition, and method of manufacture of each of the layers comprising the second exemplary structure for the metallic stack 360L are the same as in the first embodiment. Specifically, the second exemplary structure for the metallic stack 360L according to the second embodiment of the present invention may be derived from the first exemplary structure for the metallic stack 360L according to the first embodiment by omitting the processing step employed to form the top transition metal layer 50 described above. In the manufacture of the second exemplary structure for the metallic stack 360L, therefore, the exemplary metal interconnect structure is transported from the Al—Cu deposition chamber directly into the transition metal nitride deposition chamber so that the top transition metal nitride layer 60 may be formed directly on the aluminum-copper layer 40.

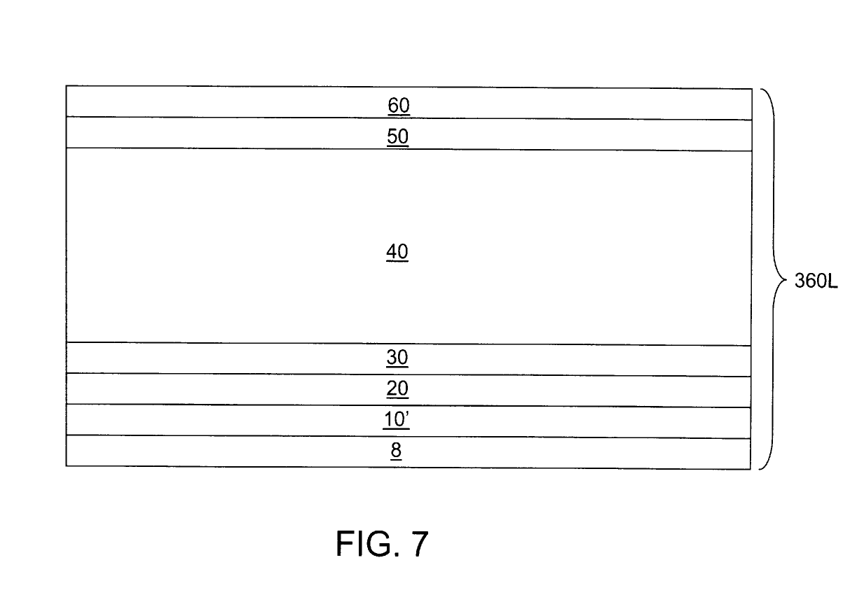

Referring to FIG. 7, a third exemplary structure for the metallic stack 360L is shown according to a third embodiment of the present invention. The third exemplary structure for the metallic stack 360L may be incorporated into the exemplary metal interconnect structure of FIG. 4 instead of the first exemplary structure for the metallic stack 360L. The second exemplary structure for the metallic stack 360L comprises, from bottom to top, a bottommost transition metal nitride layer 8, a low-oxygen-reactivity metal layer 10′, a bottom transition metal layer 20, a transition metal nitride layer 30, an aluminum-copper layer 40, a top transition metal layer 50, and a top transition metal nitride layer 60.

The structure, composition, and method of manufacture of each of the bottom transition metal layer 20, the transition metal nitride layer 30, the aluminum-copper layer 40, and the top transition metal nitride layer 60 are the same as in the first embodiment. Specifically, the third exemplary structure for the metallic stack 360L according to the third embodiment of the present invention may be derived from the first exemplary structure for the metallic stack 360L according to the first embodiment by replacing the processing step employed to form the low-oxygen-reactivity metal layer 10 described above with methods of forming a stack of the bottommost transition metal nitride layer 8 and the low-oxygen-reactivity metal layer 10′.

To incorporate the third exemplary structure of FIG. 7 as the metallic stack 360L into the exemplary metal interconnect structure as shown in FIG. 4, the exemplary metal interconnect structure of FIG. 3 is introduced into a degassing chamber at high vacuum through a transfer system provided with vacuum loadlocks. A degassing step is performed at an elevated temperature in high vacuum to desorb impurity molecules from the underlying surfaces in the same manner as described above in the first embodiment.

The exemplary metal interconnect structure is then transferred into a sputter preclean chamber, which is preferably one of chambers of the clustered toolset so that the exemplary metal interconnect structure may be transferred without breaking vacuum. The exemplary metal interconnect structure is then subjected to an inert sputtering gas such as Ar. The same sputter cleaning process may be employed as described above in the first embodiment.

Subsequently, the exemplary metal interconnect structure is transported to a transition metal nitride deposition chamber which is preferably one of chambers of the same clustered toolset to which the sputter preclean chamber belongs. In this case, the exemplary metal interconnect structure may be transferred without breaking vacuum into the transition metal nitride deposition chamber. The bottommost transition metal nitride layer 8 is formed by physical vapor deposition (PVD) of a transition metal nitride in high vacuum in the transition metal nitride deposition chamber. The bottommost transition metal nitride layer 8 is formed directly on the top surface of the underlying dielectric layer 270 and the top surface of the underlying W via 280 (See FIG. 4).

The transition metal nitride is a conductive nitride of a transition metal, in which the transition metal is selected from the elements in group III B, group IV B, group V B, group VI B, group VII B, group VIII B, group I B, and group II B of the Periodic Table of Elements. The transition metal may be one of inner transition elements, i.e., Lanthanides and Actinides. In a preferred case, the bottommost transition metal nitride layer 8 comprises TiN. In another case, the bottommost transition metal nitride layer 8 comprises TaN. Preferably, the bottommost transition metal nitride layer 8 consists of the transition metal nitride, i.e., the concentration of impurities in the bottommost transition metal nitride layer 8 is at a trace level, if any. The bottommost transition metal nitride layer 8 has a thickness from about 5 nm to about 100 nm, although lesser and greater thicknesses are also contemplated herein also. The bottommost transition metal nitride layer 8 provides enhanced adhesion between the underlying dielectric layer 270 and a low-oxygen-reactivity metal layer to be subsequently formed.

The exemplary metal interconnect structure is thereafter transferred into a low-oxygen-reactivity metal deposition chamber, which is preferably one of chambers of the clustered toolset so that the exemplary metal interconnect structure may be transferred without breaking vacuum. The low-oxygen-reactivity metal layer 10′ may be formed by physical vapor deposition (PVD) or chemical vapor deposition (CVD). Depending on the deposition method employed, the low-oxygen-reactivity metal deposition chamber may be a PVD chamber or a CVD chamber. Unlike the first embodiment, the low-oxygen-reactivity metal layer 10′ may be equally preferably formed either by physical vapor deposition in a PVD chamber or by chemical vapor deposition in a CVD chamber since the bottommost transition metal nitride layer 8 provides sufficiently enhanced adhesion between the low-oxygen-reactivity metal layer 10′ and the underlying dielectric layer 270. The low-oxygen-reactivity metal layer 10′ comprises low-oxygen-reactivity metal as elemental metal. Preferably, the low-oxygen-reactivity metal layer 10′ consists of low-oxygen-reactivity metal as elemental metal, i.e., the concentration of impurities in the low-oxygen-reactivity metal layer 10′ is at a trace level, if any. The low-oxygen-reactivity metal layer 10′ has a thickness from about 5 nm to about 100 nm, although lesser and greater thicknesses are also contemplated herein also.

Subsequently, the exemplary metal interconnect structure is transported to a transition metal deposition chamber for deposition of the bottom transition metal layer 20. Identical processing steps may be employed as in the first embodiment to form the remaining metallic layers in the third exemplary structure of the metallic stack 360L, i.e., the aluminum-copper layer 40, the top transition metal layer 50, and the top transition metal nitride layer 60.

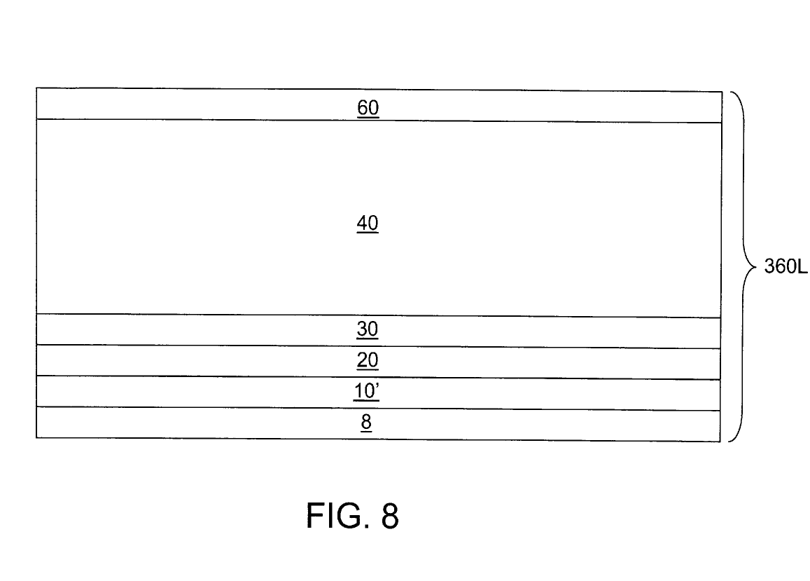

Referring to FIG. 8, a fourth exemplary structure for the metallic stack 360L is shown according to a fourth embodiment of the present invention. The fourth exemplary structure for the metallic stack 360L may be incorporated into the exemplary metal interconnect structure of FIG. 4 instead of the first exemplary structure for the metallic stack 360L. The fourth exemplary structure for the metallic stack 360L comprises, from bottom to top, a bottommost transition metal nitride layer 8, a low-oxygen-reactivity metal layer 10′, a bottom transition metal layer 20, a transition metal nitride layer 30, an aluminum-copper layer 40, and a top transition metal nitride layer 60.

The structure, composition, and method of manufacture of each of the layers comprising the fourth exemplary structure for the metallic stack 360L are the same as in the third embodiment. Specifically, the fourth exemplary structure for the metallic stack 360L according to the fourth embodiment of the present invention may be derived from the third exemplary structure for the metallic stack 360L according to the third embodiment by omitting the processing step employed to form the top transition metal layer 50 described above. In the manufacture of the fourth exemplary structure for the metallic stack 360L, therefore, the exemplary metal interconnect structure is transported from the Al—Cu deposition chamber directly into the transition metal nitride deposition chamber so that the top transition metal nitride layer 60 may be formed directly on the aluminum-copper layer 40.

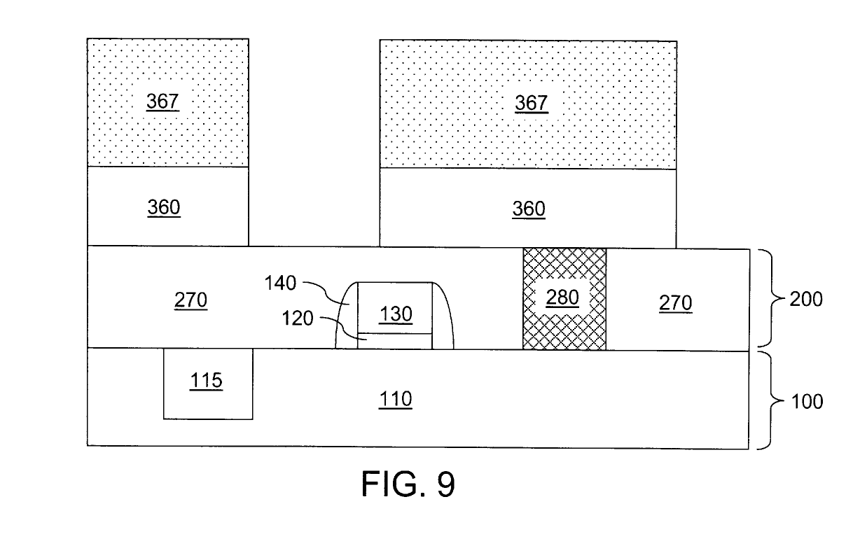

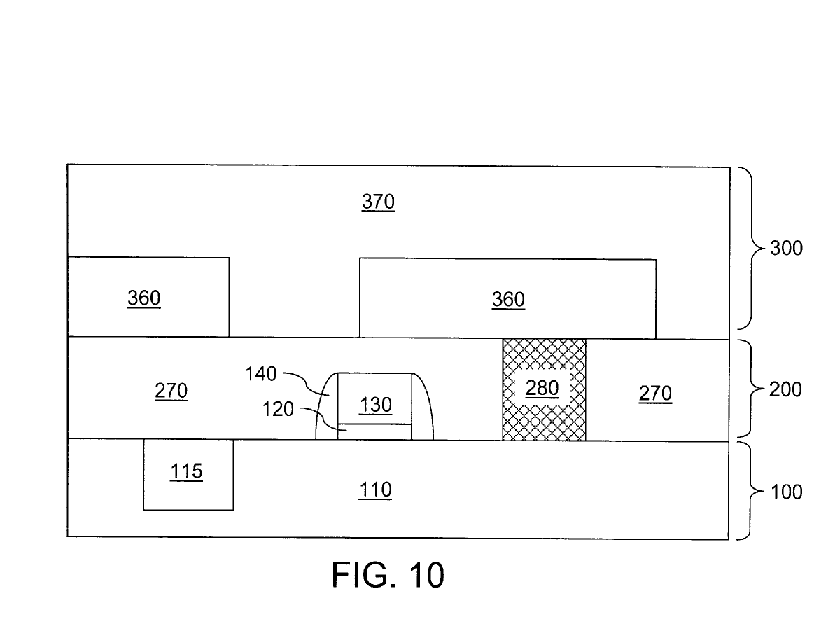

The exemplary metal interconnect structure of FIG. 4 is subsequently lithographically patterned. Referring to FIG. 9, a first photoresist 367 is applied over the top surface of the metallic stack 360L (See FIG. 4), which comprises a stack of metallic layers that collectively constitute one of the first through fourth exemplary structures of FIGS. 5-8. The first photoresist 367 is lithographically patterned in the shape of at least one metal line. The pattern in the first photoresist 367 is transferred into the stack of metallic layers by at least one anisotropic etch, which may include at least one reactive ion etch (RIE). The first photoresist 367 is employed as an etch mask throughout the at least one anisotropic etch so that the top surface of the underlying insulator layer 270 is exposed after the pattern transfer. The remaining portions of the stack of metallic layers, i.e., the remaining portions of the metallic stack 360L prior to the at least one anisotropic etch, constitute at least one metal line 360. The at least one metal line 360 has the same stack of metallic layers as the metallic stack 360L prior to the pattern transfer. Thus the at least one metal line 360 may have any one of the stacks of the first through fourth exemplary structure of FIGS. 5-8. The first photoresist 370 367 is removed after the pattern transfer.

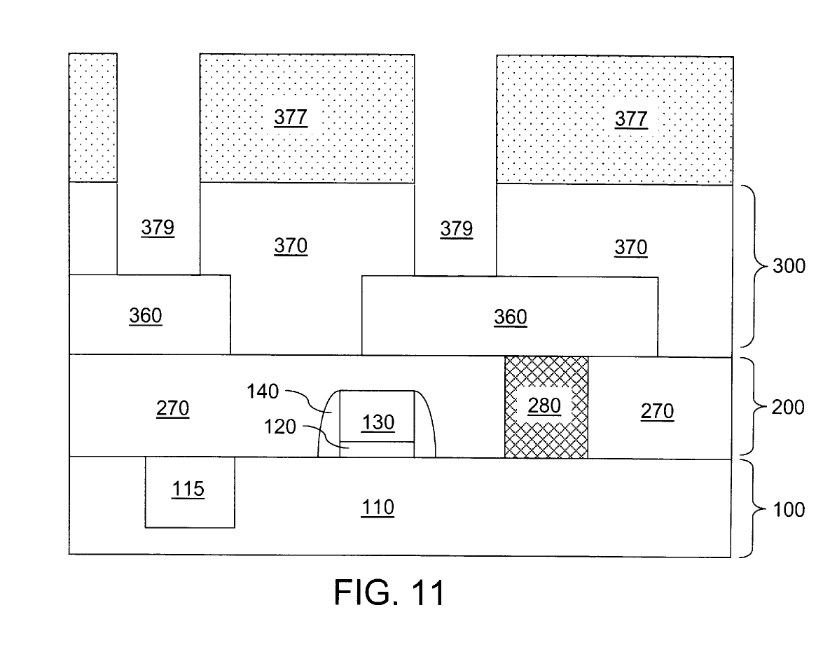

Referring to FIG. 10, a dielectric layer 370 is formed over the at least one metal line 360. Specifically, the dielectric layer 370 abuts a top surface and sidewall surfaces of each of the at least one metal line 360. Further, the dielectric layer 370 vertically abuts the top surface of the underlying dielectric layer 270.

The underlying dielectric layer 270 may comprise an oxide based dielectric material, which has a dielectric constant k from about 3.6 to about 3.9, or a low-k dielectric material, which has a dielectric constant k of about 3.0 or less, preferably less than about 2.8, and more preferably less than about 2.5. Non-limiting examples of the oxide based dielectric material included undoped silicate glass (USG), fluorosilicate glass (FSG), borophosphosilicate glass (BPSG), and phosphosilicate glass (PSG). Oxide based dielectric materials may be formed by chemical vapor deposition such as plasma enhanced chemical vapor deposition (PECVD), high density plasma chemical vapor deposition (HDPCVD), etc. An exemplary precursor that may be employed to form the oxide based dielectric material is tetra-ethyl-ortho-silicate (TEOS). Other precursors may also be employed to form a film of the oxide based dielectric material.

The dielectric layer 370 may comprise the same material as the underlying dielectric layer 270 described above. Further, the dielectric layer 370 may be formed by the same methods as the underlying dielectric layer 270. The thickness of the dielectric layer 370 may be 150 nm to about 1 μm, with a thickness from 250 to about 600 nm being more typical, although lesser and greater thicknesses are explicitly contemplated herein. The collection of material located above the top surface of the underlying interconnect level 200, i.e., the collection of the at least one metal line 360 and the dielectric layer 370, is herein referred to as an interconnect level 300.

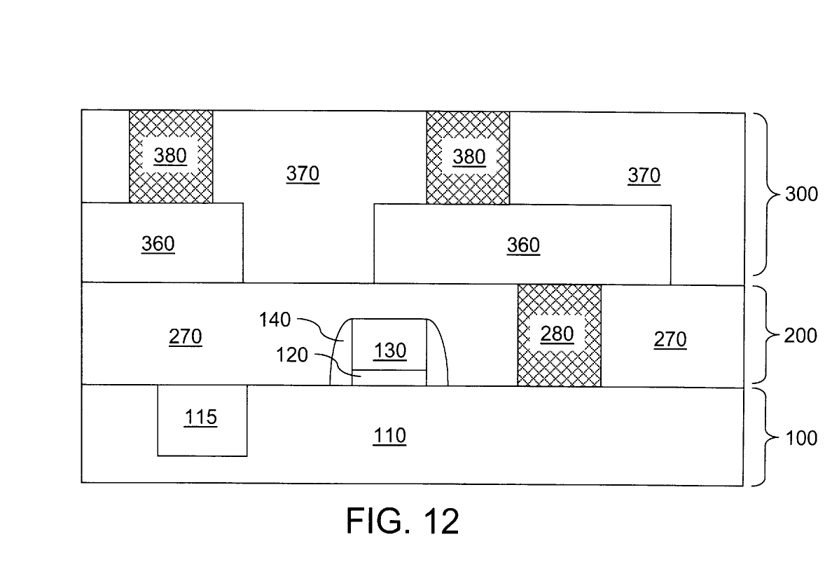

Referring to FIG. 11, a second photoresist 377 is applied over the interconnect level 300 and is lithographically patterned. The pattern in the second photoresist 377 contains at least one hole. The pattern in the second photoresist 377 is transferred into the dielectric layer 370 by an anisotropic etch, such as a reactive ion etch. The second photoresist 377 is employed as the etch mask. The anisotropic etch proceeds at least until the top surfaces of the at least one metal line 360 are exposed underneath at least one via hole 379 formed in the dielectric layer 370. The second photoresist 377 is subsequently removed.

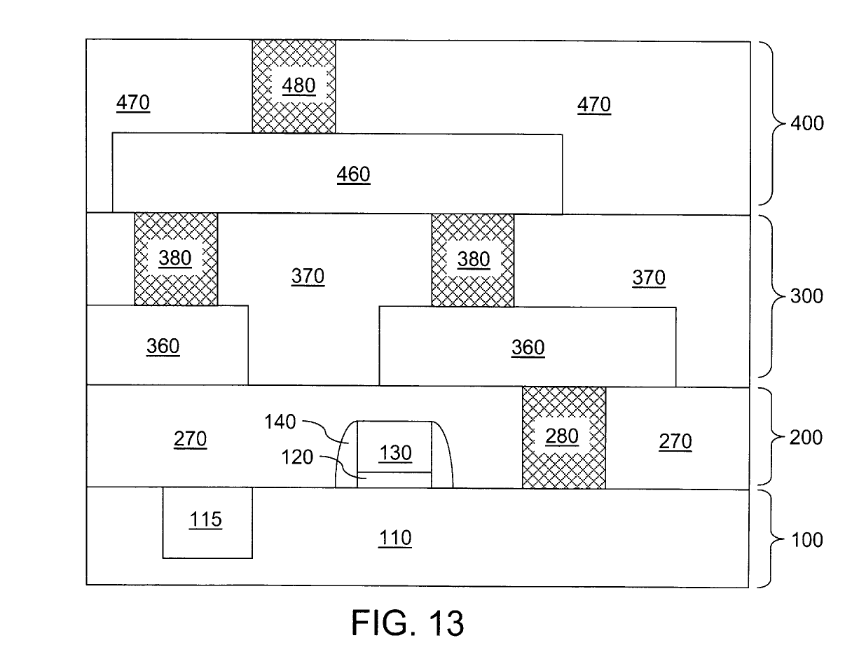

Referring to FIG. 12, low-oxygen-reactivity metal is deposited by chemical vapor deposition (CVD), physical vapor deposition (PVD), or a combination thereof. A suitable metallic liner may be deposited prior to deposition of low-oxygen-reactivity metal to enhance the adhesion of low-oxygen-reactivity metal to the dielectric layer 370 and to the at least one metal line 360. The low-oxygen-reactivity metal deposited over the top surface of the dielectric layer 370 is removed by a recess etch, chemical mechanical planarization (CMP), or a combination thereof. Removal of the portion of the low-oxygen-reactivity metal material above the top surface of the dielectric layer 370 leaves a W via 380 in each of the at least one via hole 379. In other words, the remaining portion of the low-oxygen-reactivity metal material in each of the at least one via hole 379 constitutes the W via 380. The top surface of each of the at least one W via 380 is coplanar with the top surface of the dielectric layer 370. At this point, the interconnect level 300 comprises at least one metal line 360, the dielectric layer 370, and at least one W via 380. Each of the at least one metal line 360 comprises a stack of metallic layers having the same structure as one of the first through fourth exemplary structures of FIGS. 5-8.

Referring to FIG. 13, the processing steps employed to form the interconnect level 300 may be repeated to from an overlying interconnect level 400, which comprises at least one overlying metal line 460, an overlying dielectric layer 470, and at least one overlying W via 480. The at least one overlying metal line 460 may have the same structure and composition as, and may be formed employing the same methods as, the at least one metal line 360. The overlying dielectric layer 470 may have the same structure and composition as, and may be formed employing the same methods as, the dielectric layer 370. The at least one overlying W via 480 may have the same structure and composition as, and may be formed employing the same methods as, the at least one W via 380.

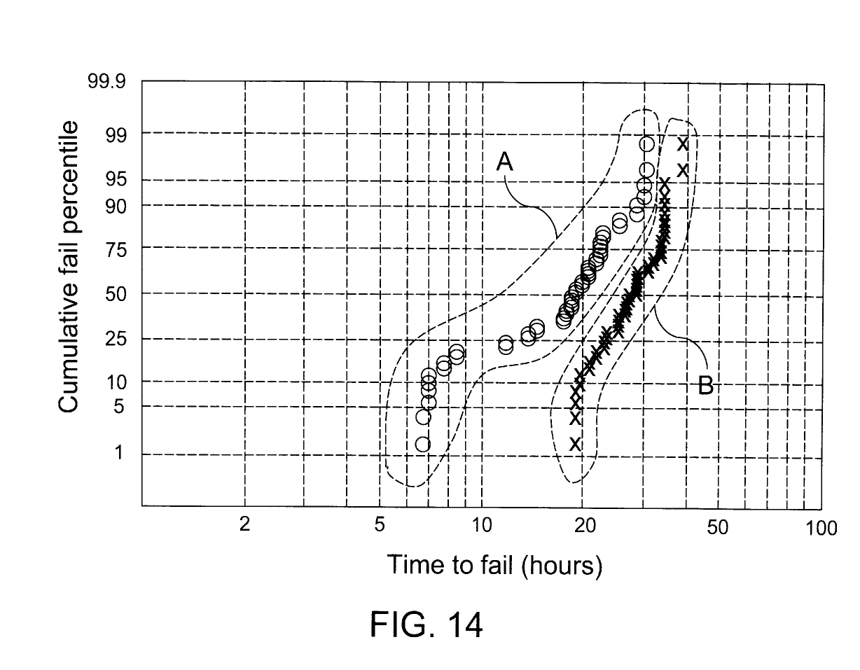

Beneficial effect of the exemplary metal interconnect structure of the present invention has been empirically verified. Referring to FIG. 14, Log-Normal plots of cumulative failure rate of a test structure containing multiple linked lines and vias as a function of a logarithm of stress time are shown for a first data set A and for a second data set B. The first data set A was generated from a first set of hardware manufactured employing the second prior art aluminum-based metal wire structure described above. The second data set B was generated from a second set of hardware manufactured employing the exemplary metal interconnect structure of the present invention. Specifically, the first exemplary structure of FIG. 5 was employed in the second set of hardware.

After measurement of initial resistance before applying any thermal stress, all the test samples were subjected to a current stress test at a constant elevated temperature of 250° C. The resistance of each sample was monitored during the anneal to detect resistance shift in time. The failure criterion is a resistance shift, i.e., increase in resistance, by more than 20% of the initial resistance of each sample. From the position and slope of the fitted line, a current density under use condition (Jᵤₛₑ) is calculated for the first set of hardware and for the second set of hardware. The current density under use condition (Jᵤₛₑ) is the maximum current density that would give a cumulative failure rate of 1.0×10⁻¹¹ per interconnect at 100 C after 100,000 hours. The current density under use condition (Jᵤₛₑ) is calculated by measuring failure rate of test structures under a test condition that accelerates electromigration failure rates. While the current density under use condition (Jᵤₛₑ) for the first set of hardware according to the prior art is about 1.3 mA/μm², the current density under use condition (Jᵤₛₑ) for the second set of hardware according to the present invention exceeds 2.0 mA/μm², which demonstrates the advantageous effects of the structures of the present invention in enhancing electromigration resistance, and thus providing a higher value for the current density under use condition (Jᵤₛₑ).

While the invention has been described in terms of specific embodiments, it is evident in view of the foregoing description that numerous alternatives, modifications and variations will be apparent to those skilled in the art. Accordingly, the invention is intended to encompass all such alternatives, modifications and variations which fall within the scope and spirit of the invention and the following claims.

What is claimed is:

1. A metal interconnect structure comprising:
an underlying dielectric layer located on a semiconductor substrate;
an underlying W via embedded in said underlying dielectric layer; and
a metal line comprising a stack of metallic layers and vertically abutting said underlying W via, wherein said stack of metallic layers comprises, from bottom to top, a low-oxygen-reactivity metal layer, a bottom transition metal layer vertically abutting said low-oxygen-reactivity metal layer, a bottom transition metal nitride layer vertically abutting said bottom transition metal layer, an aluminum-copper layer vertically abutting said bottom transition metal nitride layer, and a top transition metal nitride layer located on and above said aluminum-copper layer.

2. The metal interconnect structure of claim 1, wherein said low-oxygen-reactivity metal layer comprises an elemental metal selected from W, Mo, Ta, Pt, Co, Pd, and Ni.

3. The metal interconnect structure of claim 2, wherein said low-oxygen-reactivity metal layer comprises an elemental metal selected from W, Mo, Ta, and Pt.

4. The metal interconnect structure of claim 3, wherein said low-oxygen-reactivity metal layer comprises W as an elemental metal.

5. The metal interconnect structure of claim 1, wherein said low-oxygen-reactivity metal layer vertically abuts said underlying W via.

6. The metal interconnect structure of claim 5, wherein said top transition metal nitride layer vertically abuts said aluminum-copper layer.

7. The metal interconnect structure of claim 5, further comprising a top transition metal layer vertically abutting said aluminum-copper layer, wherein said top transition metal nitride layer vertically abuts said top transition metal layer.

8. The metal interconnect structure of claim 1, wherein said stack of metallic layers further comprising a bottommost transition metal nitride layer located underneath and vertically abutting said low-oxygen-reactivity metal layer, wherein said bottommost transition metal nitride layer abuts said underlying W via.

9. The metal interconnect structure of claim 8, wherein said top transition metal nitride layer vertically abuts said aluminum-copper layer.

10. The metal interconnect structure of claim 8, further comprising a top transition metal layer vertically abutting said aluminum-copper layer, wherein said top transition metal nitride layer vertically abuts said top transition metal layer.

11. The metal interconnect structure of claim 8, wherein said bottommost transition metal nitride layer comprises TiN.

12. The metal interconnect structure of claim 11, wherein said bottommost transition metal nitride layer comprises TiN has a thickness from about 5 nm to about 100 nm.

13. The metal interconnect structure of claim 1, wherein said underlying W via has a top surface that is coplanar with a top surface of said underlying dielectric layer.

14. The metal interconnect structure of claim 1, wherein said underlying dielectric layer comprises a dielectric material selected from undoped silicate glass (USG), fluorosilicate glass (FSG), a porous or non-porous organosilicate glass (OSG), a spin-on dielectric material having a dielectric constant less than 3.0, or a SiCOH based low dielectric constant (low-k) chemical vapor deposition (CVD) material having a dielectric constant less than 3.0.

15. The metal interconnect structure of claim 1, wherein said low-oxygen-reactivity metal layer has a thickness from about 5 nm to about 100 nm.

16. The metal interconnect structure of claim 1, wherein said bottom transition metal layer comprises Ti.

17. The metal interconnect structure of claim 1, wherein said bottom transition metal nitride layer comprises TiN.

18. The metal interconnect structure of claim 1, wherein said top transition metal nitride layer comprises TiN.

19. The metal interconnect structure of claim 1, further comprising an overlying dielectric layer abutting a top surface and sidewalls of said metal line and abutting a top surface of said underlying dielectric layer.

20. The metal interconnect structure of claim 19, wherein said overlying dielectric layer comprises a dielectric material selected from undoped silicate glass (USG), fluorosilicate glass (FSG), a porous or non-porous organosilicate glass (OSG), a spin-on dielectric material having a dielectric constant less than 3.0, or a SiCOH based low dielectric constant (low-k) chemical vapor deposition (CVD) material having a dielectric constant less than 3.0.

21. The metal interconnect structure of claim 19, further comprising another W via vertically abutting a top surface of said metal line and embedded in said overlying dielectric layer.

22. A method of forming a metal interconnect structure comprising:
forming an underlying dielectric layer on a semiconductor substrate;
forming an underlying W via within said underlying dielectric layer;
forming a low-oxygen-reactivity metal layer on said underlying dielectric layer and said W via;
forming a bottom transition metal layer directly on said low-oxygen-reactivity metal layer;
forming a bottom transition metal nitride layer directly on said bottom transition metal layer;
forming an aluminum-copper layer directly on said bottom transition metal nitride layer; and
forming a top transition metal nitride layer on said aluminum-copper layer.

23. The method of claim 22, wherein said low-oxygen-reactivity metal layer comprises an elemental metal selected from W, Mo, Ta, Pt, Co, Pd, and Ni.

24. The method of claim 22, further comprising lithographically patterning said top transition metal nitride layer, said aluminum-copper layer, said bottom transition metal nitride layer, said bottom transition metal layer, and said low-oxygen-reactivity metal layer.

25. The method of claim 24, wherein said top transition metal nitride layer, said aluminum-copper layer, said bottom transition metal nitride layer, said bottom transition metal layer, and said low-oxygen-reactivity metal layer are patterned employing a same photoresist by at least one anisotropic etch.

26. The method of claim 25, wherein remaining portions of said top transition metal nitride layer, said aluminum-copper layer, said bottom transition metal nitride layer, said bottom transition metal layer, and said low-oxygen-reactivity metal layer collectively constitute a metal line formed on and above said underlying dielectric layer and said underlying W via after said lithographical patterning.

27. The method of claim 26, wherein said remaining portion of said low-oxygen-reactivity metal layer vertically abuts said underlying W via.

28. The method of claim 26, further comprising forming a bottommost transition metal nitride layer directly on said underlying dielectric layer and said W via, wherein said low-oxygen-reactivity metal layer is formed directly on said bottommost transition metal nitride layer.

29. The method of claim 28, further comprising lithographically patterning said bottommost transition metal nitride layer employing said same photoresist.

30. The method of claim 26, wherein said top transition metal nitride layer is formed directly on said aluminum-copper layer.

31. The method of claim 26, further comprising forming a top transition metal layer directly on said aluminum-copper layer, wherein said top transition metal nitride layer is formed directly on said top transition metal layer.

32. The method of claim 26, further comprising forming an overlying dielectric layer directly on a top surface and sidewalls of said metal line and directly on a top surface of said underlying dielectric layer.

33. The method of claim 32, wherein said overlying dielectric layer comprises a dielectric material selected from undoped silicate glass (USG), fluorosilicate glass (FSG), a porous or non-porous organosilicate glass (OSG), a spin-on dielectric material having a dielectric constant less than 3.0, or a SiCOH based low dielectric constant (low-k) chemical vapor deposition (CVD) material having a dielectric constant less than 3.0.

34. The method of claim 32, further comprising forming another W via directly on a top surface of said metal line, wherein said another W via is embedded in said overlying dielectric layer.

35. The method of claim 22, further comprising:
forming a via hole in said underlying dielectric layer;
filling said via hole with W; and
removing low-oxygen-reactivity metal above a top surface of said underlying dielectric layer, wherein a remaining portion of said low-oxygen-reactivity metal in said via hole constitutes said W via.
